(19) United States
(12) Patent Application Publication
(10) Pub. No.: US 2025/0107364 A1
(43) Pub. Date: Mar. 27, 2025

(54) DISPLAY DEVICE AND METHOD OF FABRICATING THE SAME

(71) Applicant: Samsung Display Co., LTD., Yongin-si (KR)

(72) Inventors: Gwang Min CHA, Yongin-si (KR); Jun Gi KIM, Yongin-si (KR); Youn Joo RYU, Yongin-si (KR); Sang Hyun YUN, Yongin-si (KR); Jae Hun LEE, Yongin-si (KR)

(73) Assignee: Samsung Display Co., LTD., Yongin-si (KR)

(21) Appl. No.: 18/743,675

(22) Filed: Jun. 14, 2024

(30) Foreign Application Priority Data
Sep. 25, 2023 (KR) 10-2023-0127647

(51) Int. Cl. H10K 59/131; H10K 59/12; H10K 59/40

(52) U.S. Cl. CPC H10K 59/131; H10K 59/1201; H10K 59/40

(57) ABSTRACT

A display device includes a first barrier insulating layer on a first substrate and including a first contact hole, a pad having a portion on the first barrier insulating layer and another portion inserted into the first contact hole, a second barrier insulating layer including a first portion on an upper surface of the portion of the pad and a second portion on an upper surface of the another portion of the pad, a third barrier insulating layer on the second portion of the second barrier insulating layer, a coating layer on the third barrier insulating layer, a second substrate on the coating layer and the first portion of the second barrier insulating layer, a first connection line on the second substrate and electrically connected to the pad, and a flexible film including a lead electrode inserted into an open part of the first substrate.

### CROSS-REFERENCE TO RELATED APPLICATION(S)

This application claims priority to and benefits of Korean Patent Application No. 10-2023-0127647 under 35 U.S.C. § 119 filed on Sep. 25, 2023, in the Korean Intellectual Property Office, the entire contents of which are incorporated herein by reference.

### BACKGROUND

### 1. Technical Field

The disclosure relates to a display device and a method of fabricating the same.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. Display devices may be flat panel display devices such as a liquid-crystal display device, a field emission display device, and an organic light-emitting display device. Among such flat panel display devices, a light-emitting display device may include a light-emitting element that can emit light on its own, so that each of the pixels of the display panel can emit light by themselves. Accordingly, a light-emitting display device can display images without a backlight unit that supplies light to the display panel.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device that can improve reliability by way of readily recognizing an alignment key to precisely perform a photo process, and a method of fabricating the same.

Aspects of the disclosure also provide a display device that can save fabrication time and cost by way of reducing a non-display area and simplifying the fabrication process, and a method of fabricating the same.

It should be noted that objects of the disclosure are not limited to the above-mentioned objects, and other objects will be apparent to those skilled in the art from the following descriptions.

According to an embodiment, a display device may include a first substrate including an open part; a first barrier insulating layer disposed on the first substrate, the first barrier layer including a first contact hole; a pad having a portion disposed on the first barrier insulating layer and another portion inserted into the first contact hole; a second barrier insulating layer comprising a first portion disposed on an upper surface of the portion of the pad and a second portion disposed on an upper surface of the another portion of the pad; a third barrier insulating layer disposed on the second portion of the second barrier insulating layer; a coating layer disposed on the third barrier insulating layer; a second substrate disposed on the coating layer and the first portion of the second barrier insulating layer; a first connection line disposed on the second substrate and electrically connected to the pad; and a flexible film comprising a lead electrode inserted into the open part of the first substrate.

The third barrier insulating layer may absorb a wavelength of light, and the coating layer may contain an organic material.

A height of the first portion of the second barrier insulating layer may be greater than a height of the second portion of the second barrier insulating layer from an upper surface of the first substrate.

The second barrier insulating layer may further comprise a third portion that does not overlap the pad. The third barrier insulating layer and the coating layer may be disposed on the third portion of the second barrier insulating layer.

A height of the first portion of the second barrier insulating layer may be greater than a height of the third portion of the second barrier insulating layer from an upper surface of the first substrate.

The first connection line may be inserted into a second contact hole formed in the second substrate and the first portion of the second barrier insulating layer and is electrically connected to the pad.

The display device may further comprise a gate insulator disposed on the second substrate, a second connection line disposed on the gate insulator and electrically connected to the first connection line, and an interlayer dielectric layer disposed in a layer between the second connection line and the first connection line.

The display device may further comprise a contact portion covering a lower surface of the lead electrode and a lower surface of the pad to electrically connect the lead electrode to the pad.

The contact portion may be a sintered conductive ink, a metal paste, or a metal organic decomposition ink containing silver (Ag), copper (Cu), aluminum (Al), or chromium (Cr).

The lead electrode may be disposed on a lower surface of the pad by an adhesive part.

According to an embodiment, a method of fabricating a display device may include preparing a first substrate; forming a first barrier insulating layer including a first contact hole on the first substrate; forming a pad in a pad area of the first substrate, a portion of the pad being disposed on the first barrier insulating layer and another portion of the pad being inserted into the first contact hole; forming an alignment key on the first barrier insulating layer in a key area of the first substrate; forming a second barrier insulating layer comprising a first portion disposed on upper surfaces of the portion of the pad and the alignment key, and a second portion disposed on an upper surface of the another portion of the pad; forming a third barrier insulating layer on the first portion and the second portion of the second barrier insulating layer; forming a coating layer on the third barrier insulating layer; etching the coating layer disposed on the first portion of the second barrier insulating layer; and etching the third barrier insulating layer disposed on the first portion of the second barrier insulating layer.

The forming of the coating layer may comprise supplying a fluid organic solution on the third barrier insulating layer such that a thickness of the coating layer disposed on the first portion of the second barrier insulating layer is less than a thickness of the coating layer disposed on the second portion of the second barrier insulating layer.

The etching of the coating layer may comprise etching the coating layer disposed on the first portion of the second barrier insulating layer to expose the third barrier insulating layer while leaving the coating layer disposed on the second portion of the second barrier insulating layer.

The etching of the third barrier insulating layer may comprise etching the exposed third barrier insulating layer on the first portion of the second barrier insulating layer and the remaining coating layer protects the third barrier insulating layer on the second portion of the second barrier insulating layer.

The etching of the third barrier insulating layer may comprise exposing the first portion of the second barrier insulating layer.

The method may further comprise forming a second substrate on the coating layer and the first portion of the second barrier insulating layer; forming a second contact hole penetrating the second substrate and the first portion of the second barrier insulating layer to expose the pad; and forming a first connection line disposed on the second substrate and inserted into the second contact hole, the first connection line being electrically connected to the pad.

The method may further comprise separating the alignment key by cutting along a cut line between the pad area and the key area.

The method may further comprise forming an open part of the first substrate by etching a lower portion of the first substrate to expose the pad.

The method may further comprise inserting a flexible film into the open part to dispose a lead electrode of the flexible film on a lower surface of the pad.

The method may further comprise a contact portion electrically connecting the lead electrode to the pad.

According to embodiments, a barrier insulating layer that absorbs light is not in line with an alignment key in a display device, so that the alignment key can be readily recognized. As a result, a photo process can be performed precisely and the reliability can be improved. It is possible to reduce fabrication time and cost by reducing the area of the non-display area and simplifying the fabrication process.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view showing a display device according to an embodiment.

FIG. 2 is a schematic cross-sectional view showing a display device according to an embodiment.

FIG. 3 is a schematic cross-sectional view showing an example, taken along line I-I′ of FIG. 1.

FIG. 4 is a bottom view showing a display device according to an embodiment.

FIG. 5 is a schematic plan view showing a part of a non-display area of a display device according to an embodiment.

FIG. 6 is a schematic cross-sectional view showing a portion of a display device according to an embodiment.

FIG. 7 is a schematic cross-sectional view showing relationships of a pad in the display device according to an embodiment.

FIGS. 8 to 16 are schematic cross-sectional views showing processing steps of fabricating a display device according to an embodiment.

### DETAILED DESCRIPTION OF THE EMBODIMENTS

In the following description, for the purposes of explanation, numerous details are set forth in order to provide a thorough understanding of various embodiments or implementations of the disclosure. As used herein “embodiments” and “implementations” are interchangeable words that are non-limiting examples of devices or methods employing one or more of the disclosed herein. It is apparent, however, that various embodiments may be practiced without these details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like within the spirit and the scope of the disclosure. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein should be interpreted accordingly. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terminology used herein is for the purpose of describing particular embodiments and is not intended to be limiting.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

As used herein, the singular forms, “a,” “an,” and “the” are intended to include the plural forms as well, unless the context clearly indicates otherwise.

Moreover, the terms “comprises,” “comprising,” “includes,” and/or “including,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As understood in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (for example, microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (for example, one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

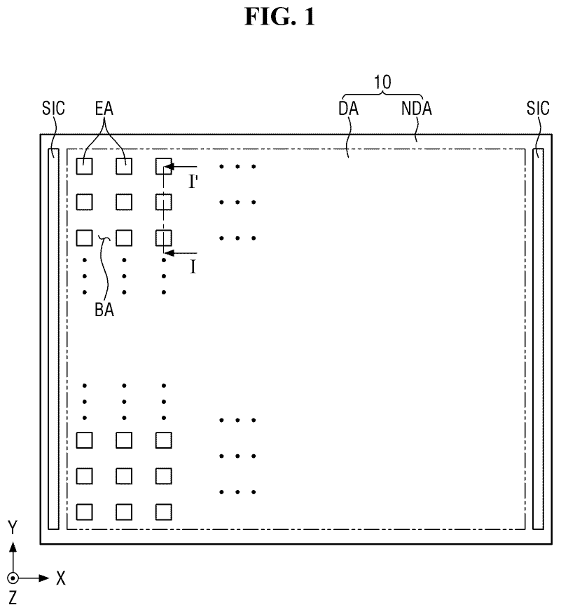

FIG. 1 is a schematic plan view showing a display device according to an embodiment.

Referring to FIG. 1, a display device 10 may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). As another example, the display device 10 may be used as a display unit of a television, a laptop computer, a monitor, an electronic billboard, or the Internet of Things (IOT). As another example, the display device 10 may be applied to wearable devices such as a smart watch, a watch phone, a glasses-type display, and a head-mounted display (HMD) device.

The display device 10 may have a shape similarly to a quadrangular shape when viewed from the top. For example, the corners where the sides in the x-axis direction and the sides in the y-axis direction meet each other may be rounded to have a selectable curvature or may be formed at a right angle. The shape of the display device 10 when viewed from the top is not limited to a quadrangular shape, but may be formed in a shape similar to other polygonal shapes, a circular shape, or an elliptical shape.

The display device 10 may include a display area DA and a non-display area NDA. The display area DA may include pixels to display images. Each of pixels may include an organic light-emitting diode including an organic light-emitting layer, a quantum-dot LED including a quantum-dot light-emitting layer, an inorganic light-emitting diode (LED) including an inorganic semiconductor, or a micro LED. In the following description, each of the pixels may include an organic light-emitting diode. It is, however, to be understood that the disclosure is not limited thereto.

The pixels may be arranged or disposed in rows and columns in the display area DA. Each of the pixels may include an emission area EA defined by a pixel-defining film or a bank, and may emit light having a selectable peak wavelength through the emission area EA. In the emission area EA, light generated by light-emitting element of the display device 10 exits out of the display device 10.

The display area DA of the display device 10 may include a light-blocking area BA surrounding the emission areas EA. The light-blocking area BA can prevent color mixing of lights output from the emission areas EA.

The non-display area NDA may be disposed around the display area DA to surround the display area DA, and may display no image. The non-display area NDA may include a scan driver SIC providing scan signals to the display area DA. The scan driver SIC may be disposed on the left side and the right side of the non-display area NDA. The scan driver SIC may generate the scan signals based on a scan control signal. The scan control signal may include, but is not limited to, a start signal, a clock signal, and a supply voltage. The scan driver SIC may provide the scan signals to scan lines of the display area DA in a selectable order.

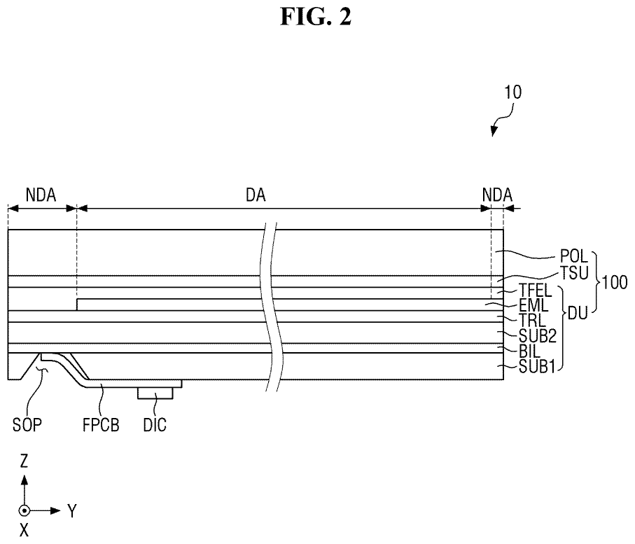

FIG. 2 is a schematic cross-sectional view showing a display device according to an embodiment.

Referring to FIG. 2, a display panel 100 may include a display unit DU, a touch sensing unit TSU, and an optical member POL. The display unit DU may include a first substrate SUB1, a barrier insulating layer BIL, a second substrate SUB2, a transistor layer TRL, an emission material layer EML, and an encapsulation layer TFEL.

The first substrate SUB1 may support the display device 10. The first substrate SUB1 may be a base substrate or a base member. The first substrate SUB1 may be a flexible substrate that can be bent, folded, or rolled. For example, the first substrate SUB1 may include, but is not limited to, an insulating material such as a polymer resin, like polyimide PI. For another example, the first substrate SUB1 may be a rigid substrate including a glass material.

The barrier insulating layer BIL may be disposed on the first substrate SUB1. The barrier insulating layer BIL may include an inorganic film that can prevent permeation of air or moisture. For example, the barrier insulating layer BIL may include, but is not limited to, at least one of: a silicon nitride layer, a silicon oxynitride layer, a silicon oxide layer, a titanium oxide layer, an aluminum oxide layer, and an amorphous silicon layer.

The second substrate SUB2 may be disposed on the barrier insulating layer BIL. The second substrate SUB2 may be a base substrate or a base member. The second substrate SUB2 may be a flexible substrate that can be bent, folded, or rolled. For example, the second substrate SUB2 may include, but is not limited to, an insulating material such as a polymer resin, like polyimide PI.

The transistor layer TRL may be disposed on the second substrate SUB2. The transistor layer TRL may include transistors forming pixel circuits of pixels. The transistor layer TRL may include scan lines, data lines, and power lines connected to the pixels. Each of the transistors may include a semiconductor region, a source electrode, a drain electrode, and a gate electrode. For example, in case that the scan driver is formed on one side or a side of the non-display area NDA of the display panel 100, the scan driver may include transistors.

The transistor layer TRL may be disposed in the display area DA and the non-display area NDA. Transistors, scan lines, data lines and power lines in the transistor layer TRL for the pixels may be disposed in the display area DA. The transistors of the scan driver SIC may be disposed in the non-display area NDA.

The emission material layer EML may be disposed on the transistor layer TRL. The emission material layer EML may include light-emitting elements in each of which a pixel electrode, an emissive layer and a common electrode are sequentially stacked each other to emit light, and a pixel-defining film for defining the pixels. The light-emitting elements in the emission material layer EML may be disposed in the display area DA.

For example, the emissive layer may be an organic light-emitting layer containing an organic material. The emissive layer may include a hole transporting layer, an organic light-emitting layer and an electron transporting layer. In case that the pixel electrode receives a voltage and the common electrode receives a cathode voltage through the transistor in the transistor layer TRL, holes may move to the organic light-emitting layer through the hole transporting layer, and electrons may move to the organic light-emitting layer through the electron transporting layer, such that they combine in the organic light-emitting layer to emit light. For example, the pixel electrode may be an anode electrode while the common electrode may be a cathode electrode. It is, however, to be understood that the disclosure is not limited thereto.

As another example, the light-emitting elements may include quantum-dot light-emitting diodes each including a quantum-dot emissive layer, inorganic light-emitting diodes each including an inorganic semiconductor, or micro light-emitting diodes.

An encapsulation layer TFEL may cover the upper and side surfaces of the emission material layer EML, and can protect the emission material layer EML. The encapsulation layer TFEL may include at least one inorganic layer and at least one organic layer for encapsulating the emission material layer EML.

The touch sensing unit TSU may be disposed on the encapsulation layer TFEL. The touch sensing unit TSU may include touch electrodes for sensing a user's touch by capacitive sensing, and touch lines providing the touch electrodes with touch driving signals. For example, the touch sensing unit TSU may sense a user's touch by mutual capacitance sensing or self-capacitance sensing.

The touch electrodes of the touch sensing unit TSU may be disposed in a touch sensor area overlapping the display area DA. The touch lines of the touch sensing unit TSU may be disposed in a touch peripheral area overlapping the non-display area NDA.

The optical member POL may be disposed on the touch sensing unit TSU. The optical member POL may be attached on the touch sensing unit TSU by using an optically clear adhesive (OCA) film or an optically clear resin (OCR). For example, the optical member POL may include a linear polarizer and a retarder film. The retarder film may be a λ/4 plate (quarter-wave plate). The retarder film and the linear polarizer may be sequentially stacked on the touch sensing unit TSU. The optical member POL can reduce reflection of external light to prevent color distortion due to the reflection of external light.

The first substrate SUB1 may include an open part SOP. The open part SOP of the first substrate SUB1 may be etched so that it penetrates from the lower surface of the first substrate SUB1 to the upper surface of the first substrate SUB1. For example, the width of the bottom of the open part SOP may be greater than the width of the top of the open part SOP. During the process of fabricating the display device 10, a pad disposed in the barrier insulating layer BIL may be exposed by the open part SOP of the first substrate SUB1. The pad may be electrically connected to a display driver DIC through a flexible film FPCB inserted into the open part SOP.

The flexible film FPCB may be disposed under (or below) the first substrate SUB1. A portion of the flexible film FPCB may be inserted into the open part SOP of the first substrate SUB1 and electrically connected to the pad. The flexible film FPCB may support the display driver DIC. The flexible film FPCB may transmit signals and voltages from the display driver DIC to the transistor layer TRL. The flexible film FPCB may supply a scan control signal to the scan driver SIC.

The display drivers DIC may be mounted on the flexible films FPCB. The display driver DIC may be an integrated circuit (IC). The display driver DIC may convert digital video data into analog data voltage based on a data control signal from a timing controller (not shown), and may supply it to the data lines in the display area DA through the flexible film FPCB. The display driver DIC may supply the power voltage received from the power supply unit (not shown) to the power lines in the display area DA through the flexible film FPCB. As the display device 10 may include the flexible film FPCB electrically connected to the pad at the open part SOP of the first substrate SUB1, the non-display area NDA can be reduced.

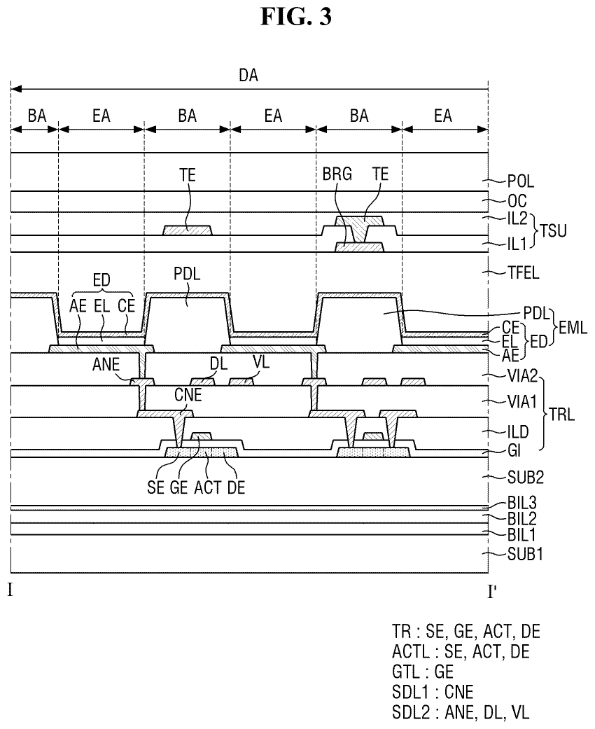

FIG. 3 is a schematic cross-sectional view showing an example, taken along line I-I′ of FIG. 1.

Referring to FIG. 3, the display area DA of the display device 10 may include emission areas EA. In each of the emission areas EA, light generated by the light-emitting element ED exits out of the display device 10.

The display panel 100 may include a first substrate SUB1, a first barrier insulating layer BIL1, a second barrier insulating layer BIL2, a third barrier insulating layer BIL3, a second substrate SUB2, a transistor layer TRL, an emission material layer EML, an encapsulation layer TFEL, a touch sensing unit TSU, an overcoat layer OC, and an optical member POL.

The first substrate SUB1 may support the display panel 100. The first substrate SUB1 may be a base substrate or a base member. The first substrate SUB1 may be a flexible substrate that can be bent, folded, or rolled. For example, the first substrate SUB1 may include, but is not limited to, an insulating material such as a polymer resin, like polyimide PI. For another example, the first substrate SUB1 may be a rigid substrate including a glass material.

The first barrier insulating layer BIL1 may be disposed on the first substrate SUB1. The first barrier insulating layer BIL1 may include an inorganic film capable of preventing permeation of air or moisture. For example, the first barrier insulating layer BIL1 may include, but is not limited to, at least one of: a silicon nitride layer, a silicon oxynitride layer, a silicon oxide layer, a titanium oxide layer, an aluminum oxide layer, and an amorphous silicon layer.

The second barrier insulating layer BIL2 may be disposed on the first barrier insulating layer BIL1. The second barrier insulating layer BIL2 may include an inorganic film capable of preventing permeation of air or moisture. For example, the second barrier insulating layer BIL2 may include, but is not limited to, at least one of: a silicon nitride layer, a silicon oxynitride layer, a silicon oxide layer.

The third barrier insulating layer BIL3 may be disposed on the second barrier insulating layer BIL2. The third barrier insulating layer BIL3 may include an inorganic film capable of preventing permeation of air or moisture. The third barrier insulating layer BIL3 can improve delamination defects by increasing the adhesion between the upper and lower layers. For example, the third barrier insulating layer BIL3 may include, but is not limited to, amorphous silicon (a-Si).

The second substrate SUB2 may be disposed on the third barrier insulating layer BIL3. The second substrate SUB2 may be a base substrate or a base member. The second substrate SUB2 may be a flexible substrate that can be bent, folded, or rolled. For example, the second substrate SUB2 may include, but is not limited to, an insulating material such as a polymer resin, like polyimide PI.

The transistor layer TRL may be disposed on the second substrate SUB2. The transistor layer TRL may include an active layer ACTL, a gate insulator GI, a gate layer GTL, an interlayer dielectric layer ILD, a first source metal layer SDL1, a first via layer VIA1, a second source metal layer SDL2, and a second via layer VIA2.

The active layer ACTL may be disposed on the second substrate SUB2. The active layer ACTL may include the semiconductor region ACT, the drain electrode DE and the source electrode SE of the transistor TR. The semiconductor region ACT may overlap a gate electrode GE direction and may be insulated from the gate electrode GE by the gate insulator GI. The drain electrode DE and the source electrode SE may be formed by making the material of the semiconductor region ACT conductive. The transistor TR may form a pixel circuit of each of pixels.

The gate insulator GI may be disposed on the active layer ACTL. The gate insulator GI may insulate between the semiconductor region ACT of the transistor TR and the gate electrode GE. The gate insulator GI may include a contact hole through which a connection electrode CNE passes.

The gate layer GTL may be disposed on the gate insulator GI. The gate layer GTL may include the gate electrode GE of the transistor TR. The gate electrode GE may overlap the semiconductor region ACT with the gate insulator GI disposed between the gate electrode GE and the semiconductor region ACT. The gate electrode GE may receive scan signals from the scan lines. For example, the gate layer GTL may be made up of a single layer or multiple layers including at least one of: molybdenum (Mo), aluminum (Al), chromium (Cr), gold (Au), silver (Ag), titanium (Ti), nickel (Ni), palladium (Pd), indium (In), neodymium (Nd), and copper (Cu).

The interlayer dielectric layer ILD may be disposed on the gate layer GTL. The interlayer dielectric layer ILD may insulate the gate layer GTL and the first source metal layer SDL1. The interlayer dielectric layer ILD may include a contact hole through which the connection electrode CNE passes.

The first source metal layer SDL1 may be disposed on the interlayer dielectric layer ILD. The first source metal layer SDL1 may include the connection electrode CNE. The connection electrode CNE may be inserted into a contact hole penetrating the interlayer dielectric layer ILD and the gate insulator GI to be connected to the source electrode SE of the transistor TR. The connection electrode CNE may electrically connect the transistor TR with an anode connection electrode ANE. The connection electrode CNE may supply a driving current received from the pixel circuit to the light-emitting element ED through the anode connection electrode ANE. For example, the first source metal layer SDL1 may be made up of a single layer or multiple layers including at least one of: molybdenum (Mo), aluminum (Al), chromium (Cr), gold (Au), silver (Ag), titanium (Ti), nickel (Ni), palladium (Pd), indium (In), neodymium (Nd), and copper (Cu).

The first via layer VIA1 may be disposed on the first source metal layer SDL1. The first via layer VIA1 can provide a flat surface over the pixel circuit and can protect the pixel circuit. The first via layer VIA1 may include an organic insulating material such as polyimide (PI). The first via layer VIA1 may include a contact hole through which the anode connection electrode ANE passes.

The second source metal layer SDL2 may be disposed on the first source metal layer SDL1. The second source metal layer SDL2 may include anode connection electrodes ANE, data lines DL, and voltage lines VL. The second source metal layer SDL2 may include the above-listed materials of the first source metal layer SDL1.

The anode connection electrode ANE may be inserted into a contact hole penetrating the first via layer VIA1 and connected to the connection electrode CNE. The anode connection electrode ANE may electrically connect the connection electrode CNE with the pixel electrode AE of the light-emitting element ED. The anode connection electrode ANE may supply the driving current received from the connection electrode CNE to the light-emitting element ED.

The data line DL may be extended in the y-axis direction in the display area DA. The data line DL may be electrically connected to the transistor TR. The data line DL may supply data voltage to the pixel circuit.

The voltage line VL may be extended in the y-axis direction in the display area DA. The voltage line VL may be electrically connected to the transistor TR or the light-emitting element ED. For example, the voltage line VL may be, but is not limited to, a high-level line, a low-level line, an initialization voltage line, a reference voltage line, or a bias voltage line.

The second via layer VIA2 may be disposed on the second source metal layer SDL2. The second via layer VIA2 can provide a flat top surface of the transistor layer TRL. The second via layer VIA2 may include an organic insulating material such as polyimide (PI). The second via layer VIA2 may include a contact hole through which the pixel electrode AE passes.

The emission material layer EML may be disposed on the transistor layer TRL. The emission material layer EML may include a light-emitting element ED and a pixel-defining layer PDL.

The light-emitting element ED may be disposed in the emission area EA on the second via layer VIA2. The light-emitting element ED of each of the pixels may include an anode electrode AE, an emissive layer EL, and a common electrode CE. The pixel electrode AE may be disposed on the second via layer VIA2. The pixel electrode AE may overlap one of the emission areas EA defined by the pixel-defining layer PDL. For example, the pixel electrode AE may receive a driving current from the pixel circuit through the anode connection electrode ANE and the connection electrode CNE.

The emissive layer EL may be disposed on the pixel electrode AE. For example, the emissive layer EL may be, but is not limited to, an organic emissive layer made of an organic material. If the emissive layer EL is an organic light-emitting layer, in case that the pixel circuit of the pixel applies a selectable voltage to the pixel electrode AE and the common electrode CE receives a common voltage or cathode voltage, holes may move to the emissive layer EL through a hole transporting layer and electrons may move to the emissive layer EL through a hole transporting layer, and they combine in the emissive layer EL to emit light.

The common electrode CE may be disposed on the emissive layer EL. For example, the common electrode CE may be implemented as an electrode common to all pixels, instead of being disposed as a separated electrode for each of the pixels. The common electrode CE may be disposed on the emissive layer EL in the emission areas and may be disposed on the pixel-defining layer PDL in the other areas than the emission area.

The pixel-defining layer PDL may be disposed in the light-blocking area BA on the second via layer VIA2. The pixel-defining layer PDL may define emission areas EA or openings. The pixel-defining layer PDL may separate and insulate the pixel electrodes AE of the pixels from one another.

The encapsulation layer TFEL may be disposed on the common electrode CE to cover the light-emitting elements ED. The encapsulation layer TFEL may include at least one inorganic film to prevent permeation of oxygen or moisture into the light-emitting elements ED. The encapsulation layer TFEL may include at least one organic film to protect the light-emitting elements ED from particles such as dust.

The touch sensing unit TSU may be disposed on the encapsulation layer TFEL. The touch sensing unit TSU may include a bridge electrode BRG, a first insulating layer IL1, touch electrodes TE, and a second insulating layer IL2.

The bridge electrode BRG may be disposed on the encapsulation layer TFEL. The bridge electrode BRG may be disposed on a different layer from the touch electrodes TE to electrically connect between adjacent touch electrodes TE.

The first insulating layer IL1 may be disposed over the bridge electrode BRG. The first insulating layer IL1 may have insulating and optical features. For example, the first insulating layer IL1 may be an inorganic layer including at least one selected from the group consisting of: a silicon nitride layer, a silicon oxynitride layer, a silicon oxide layer, a titanium oxide layer and an aluminum oxide layer. For another example, the first insulating layer IL1 may include an organic film.

The touch electrodes TE may be disposed in the light-blocking area BA on the first insulating layer IL1. The touch electrodes TE may detect a user's touch by capacitive sensing. For example, the touch sensing unit TSU may sense a user's touch by mutual capacitance sensing conducted at points between touch electrodes TE, or by self-capacitance sensing conducted on each of touch electrodes TE. The touch electrodes TE may be made up of a single layer of molybdenum (Mo), titanium (Ti), copper (Cu), aluminum (Al), or indium tin oxide (ITO), or may be made up of a stack structure of aluminum and titanium (Ti/Al/Ti), a stack structure of aluminum and ITO (ITO/Al/ITO), an APC alloy and a stack structure of an APC alloy and ITO (ITO/APC/ITO).

The second insulating layer IL2 may be disposed on the touch electrodes TE. The second insulating layer IL2 may have insulating and optical functions. The second insulating layer IL2 may be made of one of the above-listed materials as the material of the first insulating layer IL1.

The overcoat layer OC may be disposed on the touch sensing unit TSU to provide a flat top surface of the touch sensing unit TSU. For example, the planarization layer OC may include an organic insulating material.

The optical member POL may be disposed on the overcoat layer OC. The optical member POL may be attached on the touch sensing unit TSU by using an optically clear adhesive (OCA) film or an optically clear resin (OCR). For example, the optical member POL may include a linear polarizer and a retarder film. The retarder film may be a λ/4 plate (quarter-wave plate). The retarder film and the linear polarizer may be sequentially stacked on the touch sensing unit TSU. The optical member POL can reduce reflection of external light to prevent color distortion due to the reflection of external light.

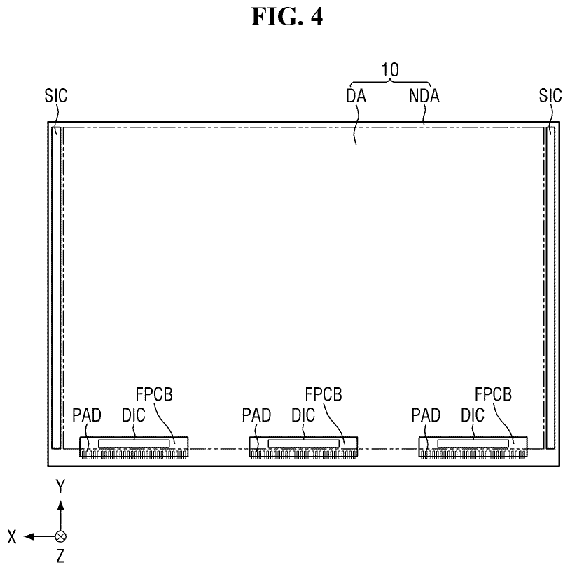

FIG. 4 is a bottom view showing a display device according to an embodiment.

Referring to FIG. 4, flexible films FPCB may be disposed under (or below) the first substrate SUB1. The flexible films FPCB may be disposed at the lower edge of the display device 100. The flexible films FPCB may be attached to the lower surfaces of the pads PAD by adhesive parts. Lead lines of the flexible films FPCB may be electrically connected to the pads PAD through contact portions. The pads PAD may be disposed in the non-display area NDA, but the disclosure is not limited thereto.

The display drivers DIC may be mounted on the flexible films FPCB. The display drivers DIC may be integrated circuits (IC). The display drivers DIC may convert digital video data into analog data voltage based on a data control signal from a timing controller (not shown), and may supply it to the data lines DL in the display area DA through the flexible films FPCB. The display drivers DIC may supply the supply voltage received from the power supply unit (not shown) to the voltage lines VL in the display area DA through the flexible films FPCB. The display drivers DIC may supply a scan control signal to the scan driver SIC through the flexible films FPCB. As the display device 10 may include the pads PAD disposed on the first substrate SUB1, and the flexible film FPCB and the display driver DIC disposed under (or below) the first substrate SUB1, the non-display area NDA can be reduced.

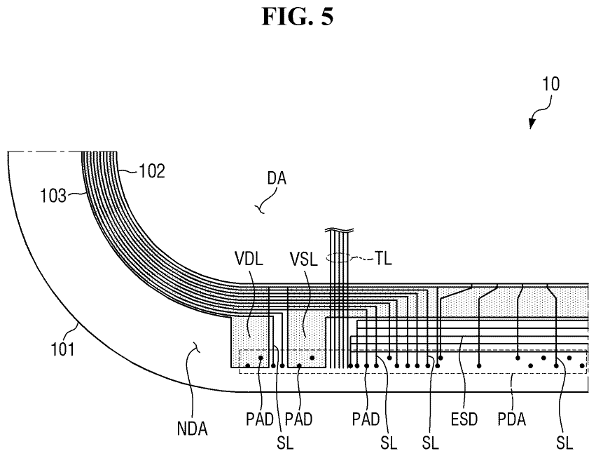

FIG. 5 is a schematic plan view showing a part of a non-display area of a display device according to an embodiment.

Referring to FIG. 5, the non-display area NDA may include signal lines SL, a high-level voltage line VDL, a low-level voltage line VSL, and touch lines TL. The signal lines SL, the high-level voltage line VDL, the low-level voltage line VSL, and the touch lines TL may be extended from a pad area PDA to the display area DA. The signal lines SL may be electrically connected to the data lines DL to apply data voltages, and may be electrically connected to the scan driver SIC to supply a scan control signal. The high-level voltage line VDL may be electrically connected to the voltage line VL of the display area DA to apply a high-level voltage to the pixel circuits. The low-level voltage line VSL may be electrically connected to the common electrode CE of the light-emitting elements ED to supply a low-level voltage. The touch lines TL may be electrically connected to the touch electrodes TE of the touch sensing unit TSU to supply touch driving signals. The signal lines SL, the high-level voltage line VDL, the low-level voltage line VSL and the touch lines TL may receive signals or voltages from the flexible films FPCB disposed under (or below) the display panel 100 through the pads PAD.

The non-display area NDA may further include an anti-static circuit ESD. The anti-static circuit ESD may overlap the signal lines SL and may be electrically connected to the signal lines SL. Accordingly, the anti-static circuit ESD can prevent external static electricity from flowing into the display area DA through the signal lines SL.

In FIG. 5, a solid line 101 indicates a border at a corner of the display panel 100. In FIG. 5, a solid line 102 is an imaginary line indicating the boundary between the non-display area NDA and the display area DA of the display panel 100. A solid line 103 in FIG. 5 indicates a border of the encapsulation layer TFEL of the display panel 100. Accordingly, the signal lines SL, the high-level voltage line VDL and the low-level voltage line VSL may be extended to the pads PAD along the non-display area NDA on the inner side of the border of the encapsulation layer TFEL. The signal lines SL, the high-level voltage line VDL and the low-level voltage line VSL may not be disposed on the outer side of the encapsulation layer TFEL.

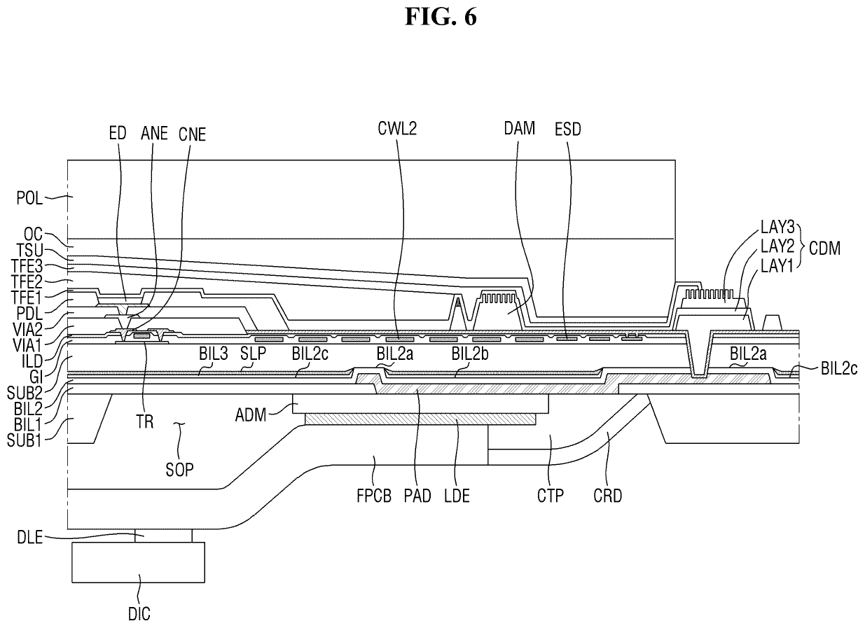

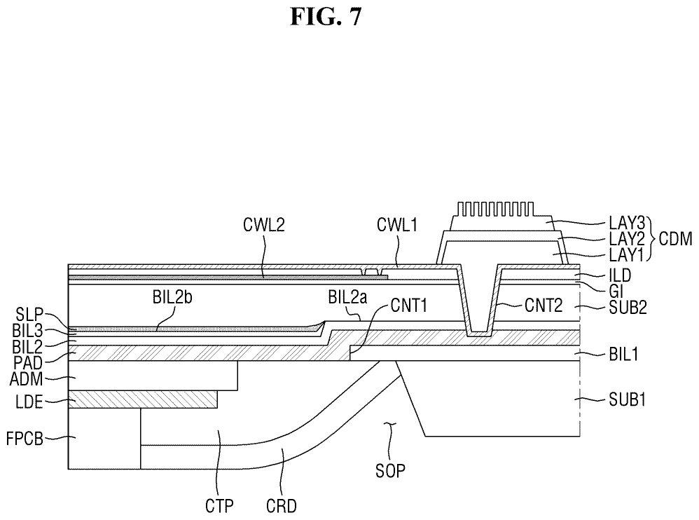

FIG. 6 is a schematic cross-sectional view showing a part of a display device according to an embodiment. FIG. 7 is a schematic cross-sectional view showing connection relationships of a pad in the display device according to an embodiment. The same elements as those described above will be briefly described or omitted.

Referring to FIGS. 6 and 7, the display device 10 may include a first substrate SUB1, a first barrier insulating layer BIL1, a pad PAD, a second barrier insulating layer BIL2, a third barrier insulating layer BIL3, a coating layer SLP, a second substrate SUB2, a transistor layer TRL, an emission material layer EML, an encapsulation layer TFEL, a dam DAM, an anti-static circuit ESD, an anti-crack member CDM, a touch sensing unit TSU, an overcoat layer OC, an optical member POL, a flexible film FPCB, and a display driver DIC.

The pad PAD may be disposed on the first barrier insulating layer BIL1 and inserted into a first contact hole CNT1 formed in the first barrier insulating layer BIL1. During the process of fabricating the display device 10, the lower surface of pad PAD may be exposed through an open part SOP of the first substrate SUB1. The pad PAD may electrically connect the flexible film FPCB with a first connection line CWL1. The pad PAD may be electrically connected to a lead electrode LDE of the flexible film FPCB through a contact portion CTP. The pad PAD may be made up of a single layer or multiple layers including at least one of: molybdenum (Mo), aluminum (Al), chromium (Cr), gold (Au), silver (Ag), titanium (Ti), nickel (Ni), palladium (Pd), indium (In), neodymium (Nd), and copper (Cu).

The second barrier insulating layer BIL2 may be disposed on the pad PAD. The second barrier insulating layer BIL2 may include a second contact hole CNT2 into which the first connection line CWL1 is inserted. During the process of fabricating the display device 10, the upper surface of the pad PAD may be exposed through the second contact hole CNT2. The second barrier insulating layer BIL2 may include first to third portions BIL2a, BIL2b and BIL2c.

For example, the first portion BIL2a of the second barrier insulating layer BIL2 may be disposed directly on the upper surface of the pad PAD disposed on the first barrier insulating layer BIL1. The first portion BIL2a of the second barrier insulating layer BIL2 may include a second contact hole CNT2. The second portion BIL2b of the second barrier insulating layer BIL2 may be disposed directly on the upper surface of the pad PAD inserted into the first contact hole CNT1. The second portion BIL2b of the second barrier insulating layer BIL2 may overlap the first contact hole CNT1. The third portion BIL2c of the second barrier insulating layer BIL2 may not overlap the pad PAD. There may be a level difference between the first portion BIL2a and the second portion BIL2b of the second barrier insulating layer BIL2. There may be a level difference between the first portion BIL2a and the third portion BIL2c of the second barrier insulating layer BIL2. The level differences of the second barrier insulating layer BIL2 may be determined by the structure of the pad PAD and the first contact hole CNT1. The height of the first portion BIL2a of the second barrier insulating layer BIL2 may be larger than the heights of each of the second portion BIL2b and the third portion BIL2c. The height of the second barrier insulating layer BIL2 may be measured from the first substrate SUB1.

The third barrier insulating layer BIL3 may be disposed on the second barrier insulating layer BIL2. A portion of the third barrier insulating layer BIL3 may overlap the first contact hole CNT1, and another portion of the third barrier insulating layer BIL3 may not overlap the pad PAD. The third barrier insulating layer BIL3 may be disposed on the second portion BIL2b and the third portion BIL2c of the second barrier insulating layer BIL2, and may not be disposed on the first portion BIL2a of the second barrier insulating layer BIL2. For example, the third barrier insulating layer BIL3 may include, but is not limited to, amorphous silicon (a-Si). The third barrier insulating layer BIL3 may absorb light during an alignment process for a photo process. For example, the third barrier insulating layer BIL3 may absorb light with a wavelength of about 600 nm or more, but the wavelength range is not limited thereto. Accordingly, a part of the pad PAD that does not overlap the third barrier insulating layer BIL3 can be readily recognized during the alignment process.

The coating layer SLP may coat the upper surface of the third barrier insulating layer BIL3. The coating layer SLP can protect the third barrier insulating layer BIL3 disposed on the second portion BIL2b and the third portion BIL2c of the second barrier insulating layer BIL2 during the process of fabricating the display device 10. Accordingly, the third barrier insulating layer BIL3 may not be disposed on the first portion BIL2a of the second barrier insulating layer BIL2 but may be disposed on the second portion BIL2b and the third portion BIL2c. For example, the coating layer SLP may include an organic material such as polyimide resin, acryl resin and cardo resin. The solid content in an organic solution forming the coating layer SLP may be equal to or less than about 5 wt %.

The second substrate SUB2 may be disposed on the coating layer SLP and the second barrier insulating layer BIL2. A portion of the second substrate SUB2 may be disposed directly on the first portion BIL2a of the second barrier insulating layer BIL2, and another portion of the second substrate SUB2 may be disposed directly on the coating layer SLP. The second substrate SUB2 may be a base substrate or a base member. The second substrate SUB2 may be a flexible substrate that can be bent, folded, or rolled. For example, the second substrate SUB2 may include, but is not limited to, an insulating material such as a polymer resin, like polyimide (PI).

The gate insulator GI may be disposed on the second substrate SUB2, and the interlayer dielectric layer ILD may be disposed on the gate insulator GI. The interlayer dielectric layer ILD, the gate insulator GI, the second substrate SUB2, and the first portion BIL2a of the second barrier insulating layer BIL2 may include a second contact hole CNT2. The second contact hole CNT2 may be etched from the upper surface of the interlayer dielectric layer ILD and penetrate to the lower surface of the first portion BIL2a of the second barrier insulating layer BIL2. Accordingly, the second contact hole CNT2 may not overlap the third barrier insulating layer BIL3 and the coating layer SLP. During the process of forming the second contact hole CNT2, the upper surface of the pad PAD may be exposed.

The first connection line CWL1 may be disposed on the interlayer dielectric layer ILD. The first connection line CWL1 may include the same material as the first source metal layer SDL1 of the display area DA and may be formed in the same process. A portion of the first connection line CWL1 may be inserted into the second contact hole CNT2 and may be in contact with the upper surface of the pad PAD. Another portion of the first connection line CWL1 may penetrate the interlayer dielectric layer ILD and may be in contact with the second connection line CWL2. The first connection line CWL1 may electrically connect the pad PAD with the second connection line CWL2. The first connection line CWL1 may supply the data voltage or power voltage received from the pad PAD to the second connection line CWL2.

The second connection line CWL2 may be disposed on the gate insulator GI. The second connection line CWL2 may include the same material as the gate layer GTL of the display area DA and may be formed in the same process. The second connection line CWL2 may supply the data voltage received from the first connection line CWL1 to the data line DL, and may supply the supply voltage received from the first connection line CWL1 to the voltage line VL. For example, the second connection line CWL2 may correspond to the signal lines SL in FIG. 5 or may be electrically connected to the signal lines SL.

The encapsulation layer TFEL may include first to third encapsulation layers TFE1, TFE2 and TFE3.

The first encapsulation layer TFE1 may be disposed on the emission material layer EML. The first encapsulation layer TFE1 may include an inorganic material to prevent oxygen or moisture from permeating into the emission material layer EML. The first encapsulation layer TFE1 may be extended to the anti-crack member CDM beyond the display area DA and the dam DAM. For example, the first inorganic layer TFE1 may include, but is not limited to, at least one of: a silicon nitride layer, a silicon oxynitride layer, a silicon oxide layer, a titanium oxide layer, an aluminum oxide layer, and an amorphous silicon layer.

The second encapsulation layer TFE2 may be disposed on the first encapsulation layer TFE1. The second encapsulation layer TFE2 may include an organic material to protect the emission material layer EML from foreign substances such as dust. The second encapsulation layer TFE2 may be extended to the dam DAM beyond the display area DA. The second encapsulation layer TFE2 may be formed by filling the area surrounded by the dam DAM. For example, the second encapsulation layer TFE2 may include an organic film such as an acrylic resin, an epoxy resin, a phenolic resin, a polyamide resin and a polyimide resin. The second encapsulation layer TFE2 may be formed by curing a monomer or applying a polymer.

The third encapsulation layer TFE3 may be disposed on the second encapsulation layer TFE2. The third encapsulation layer TFE3 may include an inorganic material to prevent oxygen or moisture from permeating into the emission material layer EML. The third encapsulation layer TFE3 may be extended to the anti-crack member CDM beyond the display area DA and the dam DAM. The third encapsulation layer TFE3 may be disposed on the second encapsulation layer TFE2 on the inner side of the dam DAM, and may be disposed on the first encapsulation layer TFE1 on the inner side of the anti-crack member CDM. For example, the third encapsulation layer TFE3 may be made of the above-listed materials as the material of the first encapsulation layer TFE1.

The dam DAM may surround the display area DA. The dam DAM may include the same material as the pixel-defining film PDL and may be formed in the same process. The dam DAM may have a selectable height so that the second encapsulation layer TFE2 containing an organic material does not flow over the dam DAM.

The anti-static circuit ESD may be disposed between the display area DA and the anti-crack member CDM. The anti-static circuit ESD may include at least one transistor. The anti-static circuit ESD may be electrically connected to the second connection line CWL2. Accordingly, the anti-static circuit ESD can prevent external static electricity from flowing into the display area DA through the second connection line CWL2.

The anti-crack member CDM may surround the dam DAM. The anti-crack member CDM may be disposed at the outermost position of the display panel 100 to prevent cracks in the display panel 100. The first and third encapsulation layers TFE1 and TFE3 and the overcoat layer OC may be formed in an area surrounded by the anti-crack member CDM.

The anti-crack member CDM may include first to third layers LAY1, LAY2 and LAY3. The first layer LAY1 of the anti-crack member CDM may cover the upper surface of the first connection line CWL1 inserted into the second contact hole CNT2. The second contact hole CNT2 may be filled with the first layer LAY1 so that the level difference may be reduced. The first layer LAY1 may include the same material as the first via layer VIA1 and may be formed in the same process.

The second layer LAY2 of the anti-crack member CDM may be disposed on the first layer LAY1. The second layer LAY2 may include the same material as the second via layer VIA2 and may be formed in the same process.

The third layer LAY3 of the anti-crack member CDM may be disposed on the second layer LAY2. The third layer LAY3 may include the same material as the pixel-defining film PDL and may be formed in the same process.

The flexible film FPCB may be disposed under (or below) the first substrate SUB1. One side or a side of the flexible film FPCB may be inserted into the open part SOP of the first substrate SUB1 and electrically connected to the pads PAD. The flexible film FPCB may include a lead electrode LDE disposed on one side or a side of the upper surface and inserted into the open part SOP. The lead electrode LDE may protrude from one side or a side of the flexible film FPCB, and the protruding part of the lead electrode LDE may not overlap the flexible film FPCB. The lead electrode LDE may be attached to the lower surfaces of the pad PAD and the first barrier insulating layer BIL1 by an adhesive part ADM. The lead electrode LDE may be electrically connected to the pad PAD through a contact portion CTP.

The flexible film FPCB may support the display driver DIC disposed on the lower surface on the opposite side. The lead electrode LDE may be electrically connected to the display driver DIC through a lead line (not shown) disposed on the lower surface of the flexible film FPCB. The other side of the flexible film FPCB may be connected to a source circuit board (not shown) under (or below) the first substrate SUB1. The flexible film FPCB may transmit signals and voltages from the display driver DIC to the display device 10. The flexible film FPCB may supply a scan control signal to the scan driver SIC.

The display drivers DIC may be mounted on the flexible films FPCB. The display drivers DIC may be integrated circuits (IC). The display driver DIC may convert digital video data into analog data voltage based on a data control signal from a timing controller (not shown), and may supply it to the data lines DL in the display area DA through the flexible film FPCB. The display driver DIC may supply the power voltage received from the power supply unit (not shown) to the voltage lines VL in the display area DA through the flexible film FPCB. As the display device 10 may include the pad PAD disposed on the first substrate SUB1, and the flexible film FPCB and the display driver DIC disposed under (or below) the first substrate SUB1, the non-display area NDA can be reduced.

The contact portion CTP may cover the lower surface of the lead electrode LDE protruding from the flexible film FPCB and the lower surface of the pad PAD exposed through the open part SOP. The contact portion CTP may electrically connect the lead electrode LDE with the pad PAD, and may stably fix the lead electrode LDE to the lower surface of the pad PAD.

For example, the contact portion CTP may be formed by low-temperature sintering a conductive ink containing nanoparticles and a polymer. The nanoparticles may contain nanoscale metal particles such as silver (Ag), copper (Cu), aluminum (Al) and chromium (Cr), and the polymer may include an acrylic resin or an epoxy resin. It should be understood, however, that the disclosure is not limited thereto. The conductive ink may contain a polymer as a binder that connects metal particles. The nanoparticles may come closer to each other and aggregate via a sintering process. The contact portion CTP including sintered nanoparticles may have conductivity.

For another example, the contact portion CTP may be formed by low-temperature sintering a metal-organic decomposition ink (MOD Ink). The metal-organic decomposition ink may contain liquid metal-organic decomposition substances smaller than nanoparticles. The liquid metal-organic decomposition substances may be converted into metal substances via a sintering process. Accordingly, the contact portion CTP may have conductivity.

The contact portion CTP may be formed by printing a conductive ink or a metal paste on the open part SOP of the first substrate SUB1 using a silicone pad, and sintering it using intense pulsed light (IPL) or a laser. During the sintering process, the metal particles come closer to each other and aggregate by heat from a light pulse or a laser, so that the resistance of the contact portion CTP may be lowered.

By way of electrically connecting the lead electrode LDE with the pad PAD through the contact portion using a metal paste, the fabrication process of the display device 10 can be simplified without using ultrasonic bonding or thermocompression bonding, so that the fabrication time and cost can be saved.

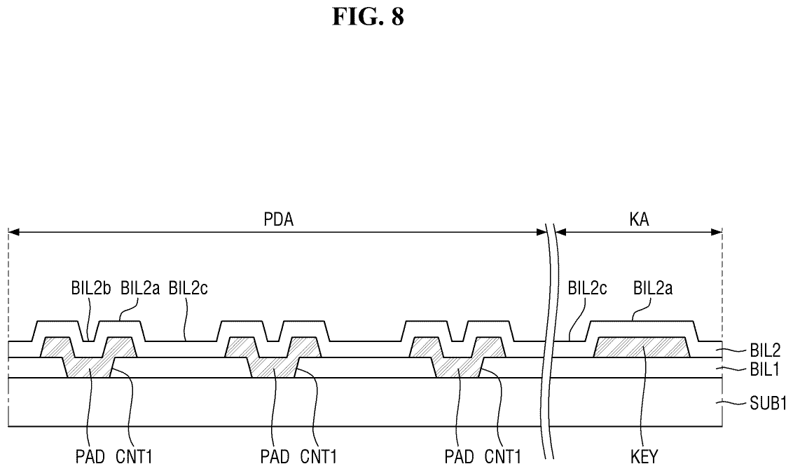

FIGS. 8 to 16 are schematic cross-sectional views showing processing steps of fabricating a display device according to an embodiment.

In FIG. 8, a first substrate SUB1 may support a display device 10. The first substrate SUB1 may be a base substrate or a base member.

The first barrier insulating layer BIL1 may be disposed on the first substrate SUB1. The first barrier insulating layer BIL1 may include an inorganic film capable of preventing permeation of air or moisture. The first barrier insulating layer BIL1 may include first contact holes CNT1.

Pads PAD may be disposed in a pad area PDA on the first barrier insulating layer BIL1. The pads PAD may be inserted into the first contact holes CNT1 formed in the first barrier insulating layer BIL1.

An alignment key KEY may be disposed in a key area KA on the first barrier insulating layer BIL1. The alignment key KEY may be used in an alignment process for a photo process. The more readily the alignment key KEY is recognized, the more accurately the alignment process can be performed and the more precisely the photo process can be performed. The alignment key KEY may include the same material as the pads PAD and may be formed in the same process.

The second barrier insulating layer BIL2 may be disposed on the pads PAD and the alignment key KEY. The second barrier insulating layer BIL2 may include an inorganic film capable of preventing permeation of air or moisture. The second barrier insulating layer BIL2 may include first to third portions BIL2a, BIL2b and BIL2c.

For example, the first portion BIL2a of the second barrier insulating layer BIL2 may be disposed directly on the upper surfaces of the pads PAD and the alignment key KEY disposed on the first barrier insulating layer BIL1. The second portion BIL2b of the second barrier insulating layer BIL2 may be disposed directly on the upper surface of the pad PAD inserted into the first contact hole CNT1. The second portion BIL2b of the second barrier insulating layer BIL2 may overlap the first contact hole CNT1. The third portion BIL2c of the second barrier insulating layer BIL2 may not overlap the pad PAD or the alignment key KEY. There may be a level difference between the first portion BIL2a and the second portion BIL2b of the second barrier insulating layer BIL2. There may be a level difference between the first portion BIL2a and the third portion BIL2c of the second barrier insulating layer BIL2. The level differences of the second barrier insulating layer BIL2 may be determined by the structure of the pads PAD, the alignment key KEY and the first contact holes CNT1. The height of the first portion BIL2a of the second barrier insulating layer BIL2 may be larger than the heights of each of the second portion BIL2b and the third portion BIL2c. The height of the second barrier insulating layer BIL2 may be measured from the first substrate SUB1.

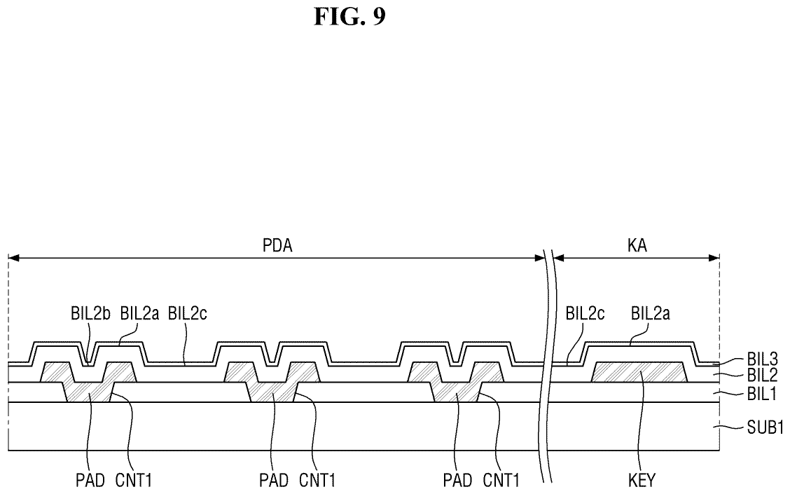

In FIG. 9, the third barrier insulating layer BIL3 may be disposed on the second barrier insulating layer BIL2. The third barrier insulating layer BIL3 may be disposed on the entire surface of the second barrier insulating layer BIL2.

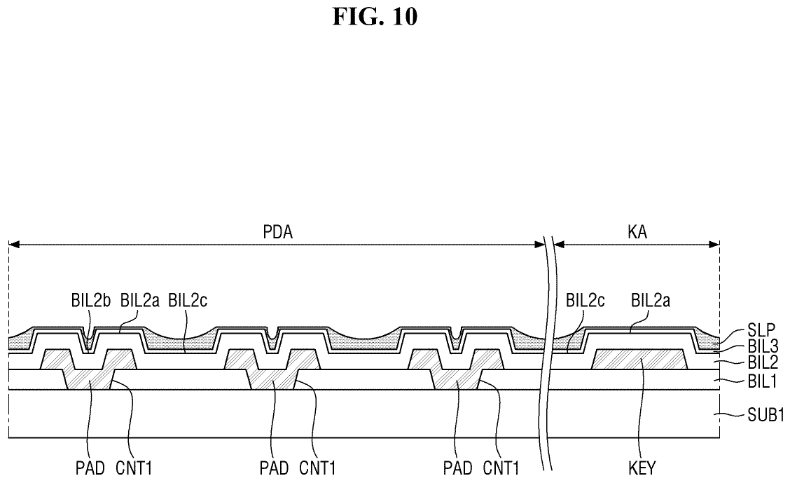

In FIG. 10, the coating layer SLP may coat the upper surface of the third barrier insulating layer BIL3. For example, the coating layer SLP may include an organic material such as polyimide resin, acryl resin and cardo resin. The solid content in an organic solution forming the coating layer SLP may be equal to or less than about 5 wt %. The coating layer SLP may have fluidity and thus may flow down due to the level differences of the second barrier insulating layer BIL2. Accordingly, the coating layer SLP may be coated relatively thinly where it overlaps the first portion BIL2a of the second barrier insulating layer BIL2, and may be coated relatively thick where it overlaps the second portion BIL2b and the third portion BIL2c of the second barrier insulating layer BIL2.

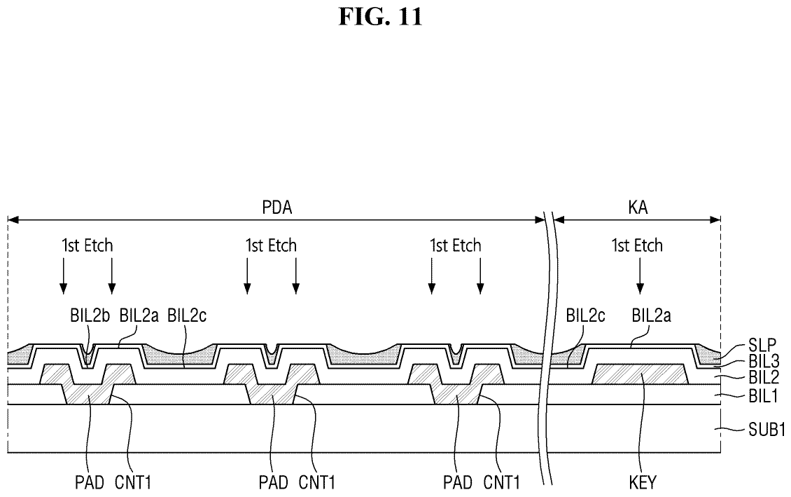

In FIG. 11, since the coating layer SLP overlapping the first portion BIL2a of the second barrier insulating layer BIL2 is coated relatively thinly, it may be etched via a 1st etch process. Since the coating layer SLP overlapping the second portion BIL2b and the third portion BIL2c of the second barrier insulating layer BIL2 is coated relatively thickly, it may remain even after the first etching process (1st etch process). For example, the 1st etch process may be, but is not limited to, a dry etching process that etches an organic film. The third barrier insulating layer BIL3 may be exposed where the coating layer SLP has been removed.

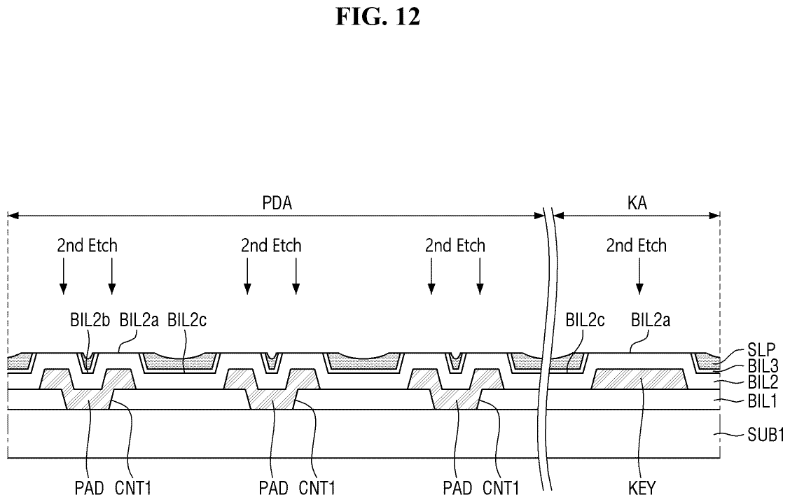

In FIG. 12, the third barrier insulating layer BIL3 exposed via the first etching (1st etch) process may be etched via a second etching (2nd etch) process. The third barrier insulating layer BIL3 disposed on the first portion BIL2a of the second barrier insulating layer BIL2 may be etched, while the third barrier insulating layer BIL3 disposed on the second portion BIL2b and the third portion BIL2c may be protected by the coating layer SLP and may not be etched. Accordingly, the first portion BIL2a of the second barrier insulating layer BIL2 may be exposed. For example, the 2nd etch process may be, but is not limited to, a dry etching process that etches an inorganic film.

As the first portion BIL2a of the second barrier insulating layer BIL2 is exposed, the alignment key KEY may not overlap the third barrier insulating layer BIL3. The third barrier insulating layer BIL3 may absorb light during an alignment process for a photo process. For example, the third barrier insulating layer BIL3 may absorb light with a wavelength of 600 nm or more, but the wavelength range is not limited thereto. Accordingly, the alignment key KEY that does not overlap the third barrier insulating layer BIL3 can be readily recognized during the alignment process. Since the photo process can be performed precisely, the reliability of the display device 10 can be improved.

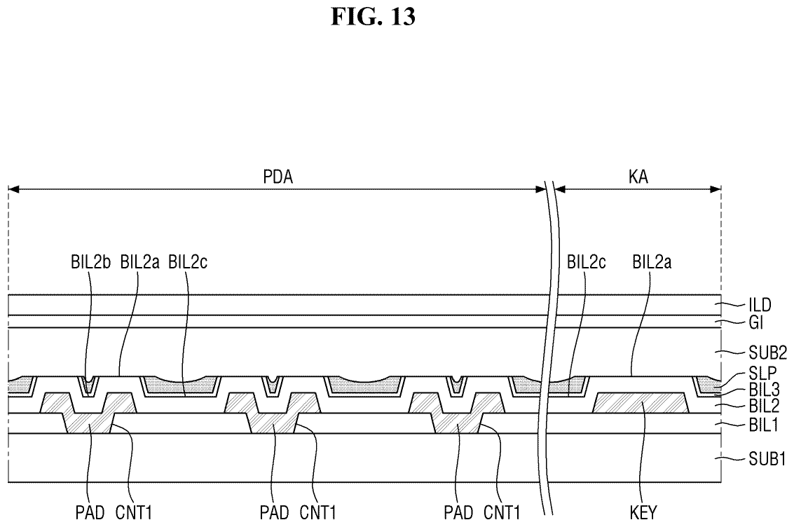

In FIG. 13, the second substrate SUB2 may be disposed on the coating layer SLP and the second barrier insulating layer BIL2. A portion of the second substrate SUB2 may be disposed directly on the first portion BIL2a of the second barrier insulating layer BIL2, and another portion of the second substrate SUB2 may be disposed directly on the coating layer SLP. The second substrate SUB2 may be a base substrate or a base member. The second substrate SUB2 may be a flexible substrate that can be bent, folded, or rolled. For example, the second substrate SUB2 may include, but is not limited to, an insulating material such as a polymer resin, like polyimide (PI).

The gate insulator GI may be disposed on the second substrate SUB2, and the interlayer dielectric layer ILD may be disposed on the gate insulator GI.

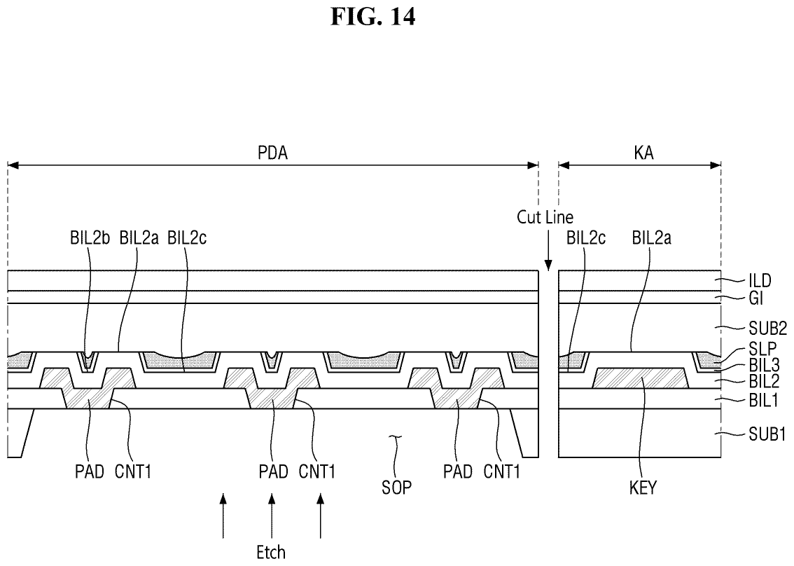

In FIG. 14, one surface or a surface of the first substrate SUB1 may be etched to form an open part SOP. The surface of the first substrate SUB1 may be subjected to at least one of: a wet etching process, a dry etching process, a plasma etching process, and a laser etching process. Since the open part SOP is formed in the first substrate SUB1, the pads PAD may be exposed. One open part SOP may expose pads PAD, but the disclosure is not limited thereto.

The pad area PDA and the key area KA may be cut and separated from each other along a cut line. The key area KA may be removed after the photo process is completed during the process of fabricating the display device 10.

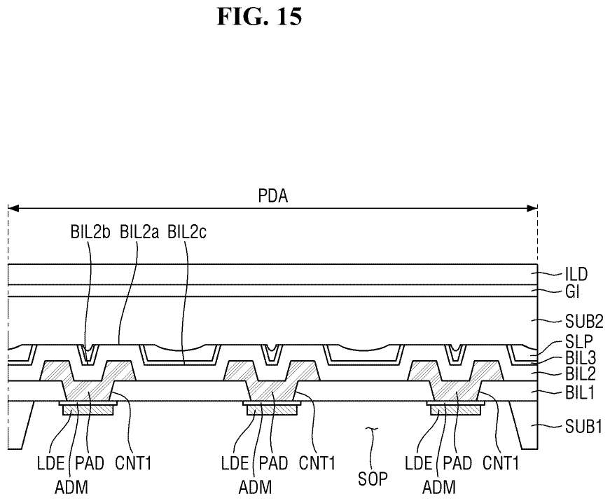

In FIG. 15, the lead electrode LDE may be inserted into the open part SOP of the first substrate SUB1. The lead electrodes LDE may be attached to the lower surfaces of the pads PAD by adhesive parts ADM.

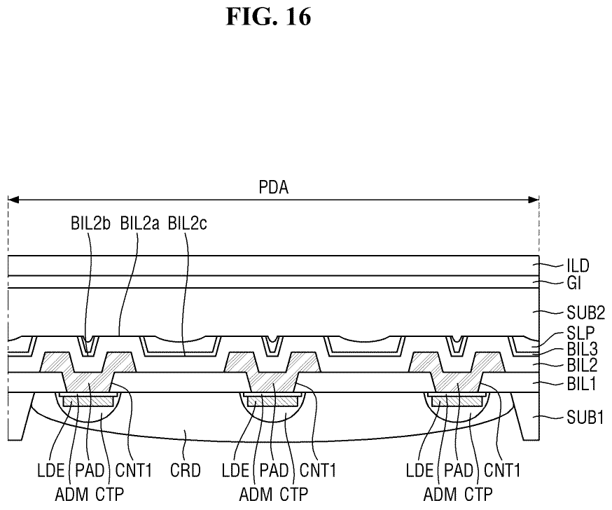

In FIG. 16, the contact portion CTP may cover the lower surface of the lead electrode LDE and the lower surface of the pad PAD. The lead electrode LDE may be electrically connected to the pad PAD through the contact portion CTP. Although the contact portions CTP and the pads (PAD) are not in direct contact with each other in FIG. 16, the contact portions CTP and the pads PAD may be in direct contact with each other in other schematic cross-sectional views, as in FIGS. 6 and 7.

A conductive ink may be applied on the lead electrodes LDE and the pads PAD. The conductive ink may contain nanoparticles and a polymer. The contact portions CTP may be formed by low-temperature sintering the conductive ink.

The sintered conductive ink, metal paste or metal-organic decomposition ink may cover pads PAD and lead electrodes LDE inserted into a single open part SOP at once. Contact portions CTP may be separated from one another via a laser patterning process. Adjacent contact portions CTP may be spaced apart from each other. One contact portion CTP may electrically connect one pad PAD with lead electrode LDE.

Therefore, in the display device 10, the lead electrode LDE and the pads PAD are electrically connected by the contact portions CTP, so that the lead electrodes LDE of the flexible films FPCB can be electrically connected to the pads PAD without using ultrasonic bonding or thermocompression bonding. By simplifying the fabrication process of the display device 10, it is possible to save the fabrication time and cost.

A cover layer CRD may be disposed on the contact portions CTP to protect the contact portions CTP. The cover layer CRD may include an organic film such as an acryl resin, an epoxy resin, a phenolic resin, a polyamide resin and a polyimide resin. The cover layer CRD may be formed by curing a monomer or applying a polymer.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure and as set forth in the following claims.

What is claimed is:

1. A display device comprising:
a first substrate including an open part;
a first barrier insulating layer disposed on the first substrate, the first barrier insulating layer including a first contact hole;
a pad having a portion disposed on the first barrier insulating layer and another portion inserted into the first contact hole;
a second barrier insulating layer comprising a first portion disposed on an upper surface of the portion of the pad and a second portion disposed on an upper surface of the another portion of the pad;
a third barrier insulating layer disposed on the second portion of the second barrier insulating layer;
a coating layer disposed on the third barrier insulating layer;
a second substrate disposed on the coating layer and the first portion of the second barrier insulating layer;
a first connection line disposed on the second substrate and electrically connected to the pad; and
a flexible film comprising a lead electrode inserted into the open part of the first substrate.

2. The display device of claim 1, wherein
the third barrier insulating layer absorbs a wavelength of light, and
the coating layer contains an organic material.

3. The display device of claim 1, wherein a height of the first portion of the second barrier insulating layer is greater than a height of the second portion of the second barrier insulating layer from an upper surface of the first substrate.

4. The display device of claim 1, wherein
the second barrier insulating layer further comprises a third portion that does not overlap the pad, and
the third barrier insulating layer and the coating layer are disposed on the third portion of the second barrier insulating layer.

5. The display device of claim 4, wherein a height of the first portion of the second barrier insulating layer is greater than a height of the third portion of the second barrier insulating layer from an upper surface of the first substrate.

6. The display device of claim 1, wherein the first connection line is inserted into a second contact hole formed in the second substrate and the first portion of the second barrier insulating layer and is electrically connected to the pad.

7. The display device of claim 1, further comprising:
a gate insulator disposed on the second substrate;
a second connection line disposed on the gate insulator and electrically connected to the first connection line; and
an interlayer dielectric layer disposed in a layer between the second connection line and the first connection line.

8. The display device of claim 1, further comprising:
a contact portion covering a lower surface of the lead electrode and a lower surface of the pad to electrically connect the lead electrode to the pad.

9. The display device of claim 8, wherein the contact portion is sintered by a conductive ink, a metal paste, or a metal organic decomposition ink containing silver (Ag), copper (Cu), aluminum (Al), or chromium (Cr).

10. The display device of claim 1, wherein the lead electrode is disposed on a lower surface of the pad by an adhesive part.

11. A method of fabricating a display device, the method comprising:
preparing a first substrate;
forming a first barrier insulating layer including a first contact hole on the first substrate;
forming a pad in a pad area of the first substrate, a portion of the pad being disposed on the first barrier insulating layer and another portion of the pad being inserted into the first contact hole;
forming an alignment key on the first barrier insulating layer in a key area of the first substrate;
forming a second barrier insulating layer comprising a first portion disposed on upper surfaces of the portion of the pad and the alignment key, and a second portion disposed on an upper surface of the another portion of the pad;
forming a third barrier insulating layer on the first portion and the second portion of the second barrier insulating layer;
forming a coating layer on the third barrier insulating layer;
etching the coating layer disposed on the first portion of the second barrier insulating layer; and
etching the third barrier insulating layer disposed on the first portion of the second barrier insulating layer.

12. The method of claim 11, wherein the forming of the coating layer comprises:
supplying a fluid organic solution on the third barrier insulating layer such that a thickness of the coating layer disposed on the first portion of the second barrier insulating layer is less than a thickness of the coating layer disposed on the second portion of the second barrier insulating layer.

13. The method of claim 12, wherein the etching of the coating layer comprises:
etching the coating layer disposed on the first portion of the second barrier insulating layer to expose the third barrier insulating layer while leaving the coating layer disposed on the second portion of the second barrier insulating layer.

14. The method of claim 13, wherein the etching of the third barrier insulating layer comprises:
etching the exposed third barrier insulating layer on the first portion of the second barrier insulating layer and the remaining coating layer protects the third barrier insulating layer on the second portion of the second barrier insulating layer.

15. The method of claim 14, wherein the etching of the third barrier insulating layer comprises exposing the first portion of the second barrier insulating layer.

16. The method of claim 15, further comprising:
forming a second substrate on the coating layer and the first portion of the second barrier insulating layer;
forming a second contact hole penetrating the second substrate and the first portion of the second barrier insulating layer to expose the pad; and
forming a first connection line disposed on the second substrate and inserted into the second contact hole the first connection line being electrically connected to the pad.

17. The method of claim 16, further comprising:
separating the alignment key by cutting along a cut line between the pad area and the key area.

18. The method of claim 16, further comprising:
forming an open part of the first substrate by etching a lower portion of the first substrate to expose the pad.

19. The method of claim 18, further comprising:
inserting a flexible film into the open part to dispose a lead electrode of the flexible film on a lower surface of the pad.

20. The method of claim 19. further comprising:
a contact portion electrically connecting the lead electrode to the pad.
